(19) United States
(12) Patent Application Publication
(10) Pub. No.: US 2025/0251479 A1
(43) Pub. Date: Aug. 7, 2025

(54) SYSTEMS AND METHODS FOR MAGNETIC RESONANCE IMAGE SYNTHESIS

(71) Applicants: Case Western Reserve University, Cleveland, OH (US); The University of North Carolina at Chapel Hill, Chapel Hill, NC (US)

(72) Inventors: Dan Ma, Solon, OH (US); Pew-Thian Yap, Chapel Hill, NC (US); Richard James Adams, Cleveland, OH (US)

(21) Appl. No.: 19/046,347

(22) Filed: Feb. 5, 2025

Related U.S. Application Data
(60) Provisional application No. 63/549,945, filed on Feb. 5, 2024.

(51) Int. Cl. G01R 33/56; G06T 7/00

(52) U.S. Cl. CPC G01R 33/5608; G06T 7/0012; G06T 2207/10088; G06T 2207/20081

(57) ABSTRACT

A method for synthesizing magnetic resonance (MR) images with a plurality of contrasts includes generating, using a processor device, a contrast dictionary using a physics-based signal model, retrieving, using the processor device, a plurality of quantitative tissue maps for an anatomy of interest for one or more subjects, synthesizing, using the processor device, a plurality of MR images with a plurality of contrasts using the plurality of quantitative tissue maps and the contrast dictionary, and storing, using the processor device, the plurality of synthesized MR images in a data storage.

### CROSS-REFERENCE TO RELATED APPLICATIONS

This application is based on, claims priority to, and incorporates herein by reference in its entirety U.S. Ser. No. 63/549,945 filed Feb. 5, 2024 and entitled “Systems and Methods for Image Synthesis Framework.”

### STATEMENT REGARDING FEDERALLY SPONSORED RESEARCH

This invention was made with government support under CA269604, CA282516, EB008374, MH125479, and NS109439 awarded by the National Institutes of Health. The government has certain rights in the invention.

### BACKGROUND

Magnetic resonance imaging (MRI) offers a myriad of soft-tissue contrasts that are useful in physics, biology, and medicine. By altering the contrast, radiologists can enhance specific tissue properties, such as water content, fat, or blood flow, facilitating the identification of conditions like tumors, inflammation, bleeding, and other pathologies. Different MRI contrast types, such as T1-weighted, T2-weighted, and diffusion-weighted images, provide complementary information that aids comprehensive clinical assessment and diagnosis. However, undesirable contrast variations may also arise from differences in imaging equipment, acquisition sequences, or subjective preferences. Contrast variations can cause inconsistent interpretation, diagnostic errors, and reduced reproducibility. They also pose challenges in automated analysis—MRI computational tools that rely on specific contrast settings may struggle to extract true tissue properties when faced with varying contrast. In large-scale datasets, contrast variability complicates the integration and analysis of data from different sources, reducing their collective utility.

There is a need for systems and methods for synthesizing MR images with a plurality of contrasts that can be used, for example, for machine learning of contrast generalizable applications or tasks.

### SUMMARY OF THE DISCLOSURE

In accordance with an embodiment, a method for synthesizing magnetic resonance (MR) images with a plurality of contrasts includes generating, using a processor device, a contrast dictionary using a physics-based signal model, retrieving, using the processor device, a plurality of quantitative tissue maps for an anatomy of interest for one or more subjects, synthesizing, using the processor device, a plurality of MR images with a plurality of contrasts using the plurality of quantitative tissue maps and the contrast dictionary, and storing, using the processor device, the plurality of synthesized MR images in a data storage.

In accordance with another embodiment, a system for synthesizing magnetic resonance (MR) images with a plurality of contrasts includes a memory that stores one or more computer readable media that includes instructions, and one or more processor devices configured to execute the instructions of the computer readable media to generate a contrast dictionary using a physics-based signal model, retrieve a plurality of quantitative tissue maps for an anatomy of interest for one or more subjects, synthesize a plurality of MR images with a plurality of contrasts using the plurality of quantitative tissue maps and the contrast dictionary, and store the plurality of synthesized MR images in a data storage.

### BRIEF DESCRIPTION OF THE DRAWINGS

The present invention will hereafter be described with reference to the accompanying drawings, wherein like reference numerals denote like elements.

FIG. 1 illustrates a method for synthesizing magnetic resonance (MR) images with a plurality of contrasts using a physics-based contrast dictionary and quantitative tissue maps in accordance with an embodiment;

FIG. 2 illustrates a method for training a generalizable AI model for a magnetic resonance imaging application using synthesized MR training images with a plurality of contrasts in accordance with an embodiment;

FIG. 3 illustrates a method for generating a consensus segmentation for an anatomy of a subject using synthesized MR images with a plurality of contrasts in accordance with an embodiment;

FIG. 4 illustrates a method for evaluating a plurality of trained AI models for an MR application using synthesized MR images with a plurality of contrasts in accordance with an embodiment;

FIG. 5 illustrates a method for determining an optimal contrast for an MR application using a contrast dictionary in accordance with an embodiment;

FIG. 6 is schematic diagram of an example magnetic resonance imaging (MRI) system in accordance with an embodiment; and

FIG. 7 is a block diagram of an example computer system in accordance with an embodiment.

### DETAILED DESCRIPTION

Artificial intelligence (AI) or machine learning (ML) networks for MRI often lack generalizability beyond their training data. This can pose challenges, for example, in distinguishing actual tissue characteristics from contrast variations. Insufficient consideration of contrast deviations throughout the AI development life cycle-including data annotation (or labeling), network learning, and model deployment-limits AI accuracy, reliability, and adaptability. Given the practical impossibility of gathering in vivo training images encompassing all conceivable contrasts, contemporary approaches to improve magnetic resonance (MR) image generalization mainly revolve around synthesizing contrasts for data augmentation during network training. These methods utilize either generative models or MR signal models. Generative model-based approaches employ domain randomization to generate images with unrealistic but extreme contrast variations to enhance generalizability. Alternatively, MR signal model-based approaches generate contrasts from quantitative tissue maps using signal equations associated with MR sequences.

These approaches, while demonstrated to be effective, have important limitations. Firstly, generative models often overlook the impact of MR imaging mechanisms and natural tissue transitions on image contrasts. This opens the door to generating unrealistic image contrasts, posing a risk of misleading network training and hindering the network's ability to generalize across real-world data. Secondly, existing MR model approaches are constrained to one or two sequences that can be represented as static signal equations, only scratching the surface of possible contrasts. For example, one conventional MR model approach deals primarily with T1-weighted images generated with magnetization-prepared rapid gradient-echo (MPRAGE) and spoiled gradient echo (SPGR) sequences. This calls into question their generalizability to unforeseen contrasts. Thirdly, synthesized contrasts find predominant use solely in model training, sidelining their potential impact on the development life cycle of an AI model. Notably, their application in data labeling and performance benchmarking is conspicuously overlooked, despite the undeniable significance of these steps in AI development. These limitations undermine the potential of synthetic contrasts in developing AI models that that are capable of handling (or processing) all possible variations of MRI scans (e.g., pan-contrast AI models).

The present disclosure describes systems and methods for a physics-driven image synthesis framework that can be utilized for machine learning (e.g., training of AI models or networks) of contrast generalizable applications or tasks. The disclosed systems and methods for synthesizing MR images with a plurality of contrasts may also be referred to herein as “UltimateSynth.” The disclosed systems and methods for synthesizing MR images can be used for training an AI model for contrast-specific and contrast-invariant tasks such as, for example, segmentation (e.g., tissue segmentation), harmonization (e.g., multi-site image harmonization), super-resolution (e.g., enhancing the quality and resolution of MRI scans beyond their original acquisition parameters), spatial normalization (e.g., aligning images to a standard anatomical template for comparative analysis across studies or populations), anomaly detection (e.g., identifying unusual patterns that may indicate disease or abnormalities), image registration and image enhancement, healthy brain atlas generation, healthy/aging brain characterization, and disease detection and characterization. Advantageously, the disclosed systems and methods for synthesizing MR images can generate a comprehensive range of image contrasts for machine/deep learning of contrast generalizable tasks and can generate any possible MR image contrast on demand. The methods for MR image synthesis are informed by MR physics but are not constrained by actual tissue or scan parameters including actual scanner limitations. In some embodiments, a contrast dictionary may be generated using a physics-based signal model (e.g., the Bloch equations, the Bloch-Torrey equations). Accordingly, the contrast dictionary can be generated to include a wide range of diverse image contrasts (e.g., common, uncommon, and unachievable contrasts) by exploring the entire MR encoding space (such as excitation, scan timing, sampling, and resolution), system imperfections (such as B0 and B1 inhomogeneities), and the tissue property space (such as T1, T2, and diffusion). A plurality of quantitative tissue maps (also referred to herein as quantitative maps, tissue maps, or quantitative tissue parameter maps) for a particular anatomy of interest and from one or more subjects can be used with the contrast dictionary to synthesize MR images with a plurality of contrasts.

As mentioned, the synthesized MR images can be used for training an AI model (or network) to perform contrast generalizable applications or tasks. Advantageously, the image synthesis systems and methods can facilitate various key stages of the development lifecycle of generalizable AI models (or networks) including, for example, data labeling, machine learning emulation (e.g., generalizable model training), and model deployment (e.g. performance benchmarking). In some embodiments, the disclosed systems and methods for synthesizing MR images with a plurality of contrast advantageously integrate quantitative tissue property mapping with physics-driven contrast synthesis to, for example, improve ground truth generation for AI network training, enable principled training of contrast-specific and contrast-invariant networks, and allow comprehensive performance evaluation with respect to contrast variation. In some embodiments, the synthesized MR images can be used to achieve pan-contrast generalizability for AI networks (or models) and enables knowledge learned with a specific image contrast to be transferred to one or more alternative contrasts. In some embodiments, the synthesized MR images with a plurality of contrasts can be used to estimate a consensus segmentation for anatomy of a subject. In some embodiments, labeling efficiency may be improved by generating a variety of images with different contrasts from the same anatomy as well as customized image contrasts.

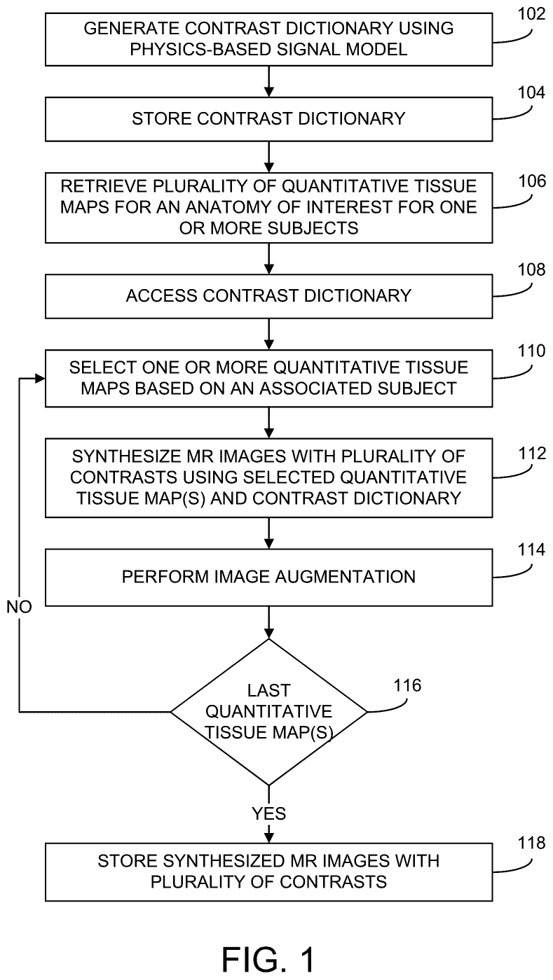

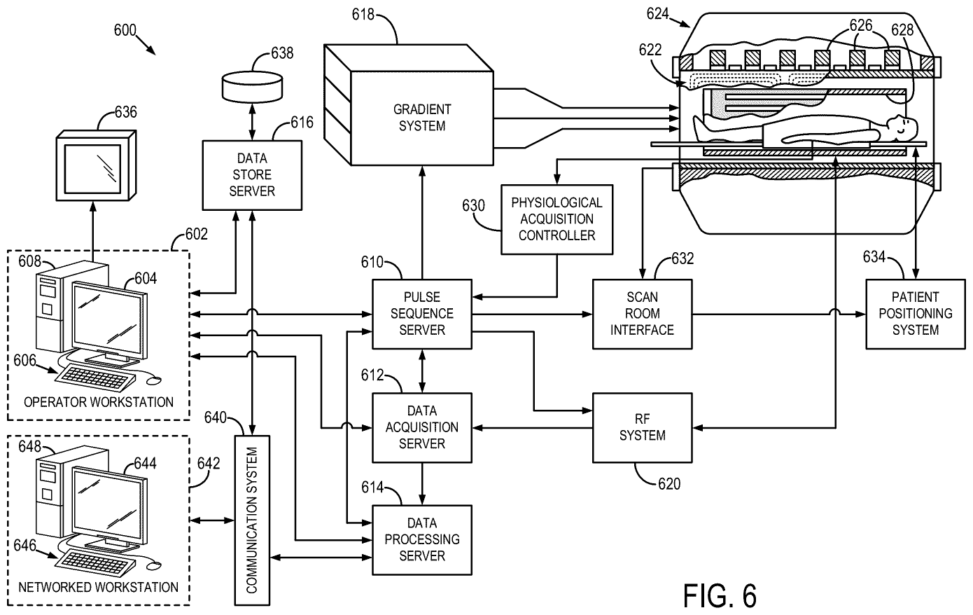

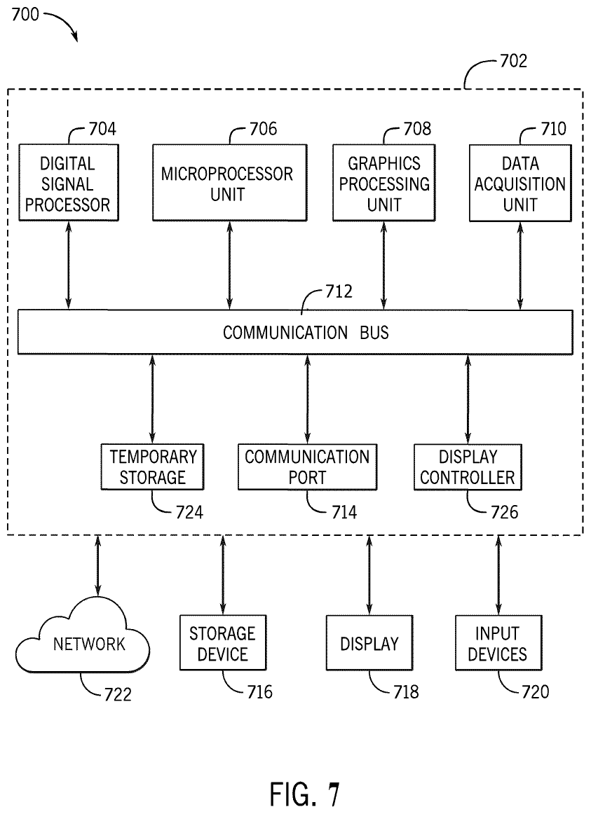

FIG. 1 illustrates a method for synthesizing magnetic resonance (MR) images with a plurality of contrasts using a physics-based contrast dictionary and quantitative tissue maps in accordance with an embodiment. Although the blocks of the process of FIG. 1 are illustrated in a particular order, in some embodiments, one or more blocks may be executed in a different order than illustrated in FIG. 1, or may be bypassed. The process of FIG. 1 may be performed by a processing system including at least one electronic processor, where the at least one electronic processor may be or include a processor as described below (e.g., including one or more individual processor devices) with respect to FIGS. 6 and 7. For example, the process of FIG. 1 may be performed using a processor of MRI system 100 (e.g., processor 608) described below with respect to FIG. 6 or computer system 700 described below with respect to FIG. 7.

At block 102, a contrast dictionary may be generated using a physics based signal model. In some embodiments, the physics-based signal model may be associated with a particular anatomy of interest of a subject, for example, the brain, the heart, breasts, knees, prostate, etc. It should be understood that the systems and methods described herein can be used with any anatomy of interest (or part of the body) of the subject. In some embodiments, the physics-based signal model can include, but is not limited to, the Bloch equations, the Bloch-Torrey equations, etc. In some embodiments, the physics-based signal model is a classic spin dynamics model that models classical nuclear spin dynamics without assumptions about anatomy or scan details. In MRI, the acquired signal can be determined by both intrinsic tissue properties, such as, for example, relaxation times, proton density, diffusion, and hemodynamics, and extrinsic imaging factors, including, for example, the static magnetic field (B0), radiofrequency (RF) field (B1), and acquisition timings (e.g., echo time (TE) and repetition time (TR). The physics-based signal model can be used to create (e.g., simulate or synthesize) a dictionary of signals (e.g., magnetization signals) for contrasts and contrast combinations that can include a full spectrum of image contrasts across a complete range of combinations of imaging factors or scan parameters (e.g., initial magnetization, RF pulses, TR, TE, and phase from a set of tissue properties (e.g., T1, T2, proton density). The signals simulated with the physics-based signal model can include, for example, typical image contrasts from clinical scans, extreme contrasts attainable only through aggressive MR scanner setting, and suboptimal contrasts that may occur during routine acquisitions. The contrasts can include, but are not limited to, for example, T1-weighted, T2-weighted, diffusion-weighted, susceptibility-weighted, FLAIR (fluid-attenuated inversion recovery), and BOLD (blood oxygen level dependent). Advantageously, the physics-based signal model can be used to synthesize or simulate signals for contrasts beyond the physical limits of MRI scanners (e.g., MRI system 600 shown in FIG. 6) and sequences, which can advantageously equip AI models trained with the MR images synthesized using the contrast dictionary to handle unforeseen imaging variations. The contrast dictionary is configured to transcend the limitations of physical scanners and cover a vast spectrum of tissue parameters.

Advantageously, by using a physics-based signal model, the simulated signals for different contrasts in the contrast dictionary integrate intrinsic tissue properties, quantified through nuclear spin relaxation, and extrinsic imaging factors (or scan parameters), such as, for example, static magnetic field, radiofrequency pulse, and acquisition timings. Accordingly, the contrast dictionary provides a contrast landscape using physics-informed combinations of diverse tissue and scan parameters. The generated contrast dictionary can provide a comprehensive dictionary of signal magnetizations that reflect the combined effects of intrinsic tissue parameters (such as T1- and T2-relaxation times and proton density) and extrinsic acquisition parameters that determine contrast mechanisms (such as, for example, initial magnetization, pulse timings, and radiofrequency excitations).

In some embodiments, the contrast dictionary (D) can be an image contrast landscape that can be encoded as a two-dimensional dictionary matrix. The rows of the dictionary can represent contrast values for one type of contrast (e.g., T1, T2, diffusion, etc.) or all combinations of two or more contrast values (e.g., combinations of T1 and T2, combinations of T1, T2, and diffusion, etc.). The columns can encode all the different combinations of imaging factors (or scan parameters), for example, TR, RF, TE, etc. used to generate a signal with a given contrast(s). Accordingly, each row includes a plurality of simulated signals for a particular contrast value or combination of contrast values and each signal can be simulated with the physics-based signal model using a different combination of imaging factors (or scan parameters). In some embodiments, a range of the different tissue contrasts to be simulated and a range of values for each imaging factor or parameter varied in the process of generating the signals in the dictionary can be predetermined and thereby limit the number of dictionary entries. In one example, T1 and T2 values can have a predetermined range from 0 to 5000 milliseconds, RF values can have a predetermined range from 0 to 90 degrees, and TE values can have a predetermined range of 1 to 400 milliseconds. As mentioned, the contrast dictionary can be generated using one or more processor devices. At block 104, the generated contrast dictionary can be stored in data storage or memory of, for example, an MRI system (e.g., MRI system 600 shown in FIG. 6) or a computer system (e.g., computer system 700 shown in FIG. 7). In some embodiments, a contrast dictionary can be generated in real time for synthesizing MR images. In some embodiments, the process in FIG. 1 can use a contrast dictionary that was previously generated. Accordingly, the contrast dictionary can be retrieved from data storage.

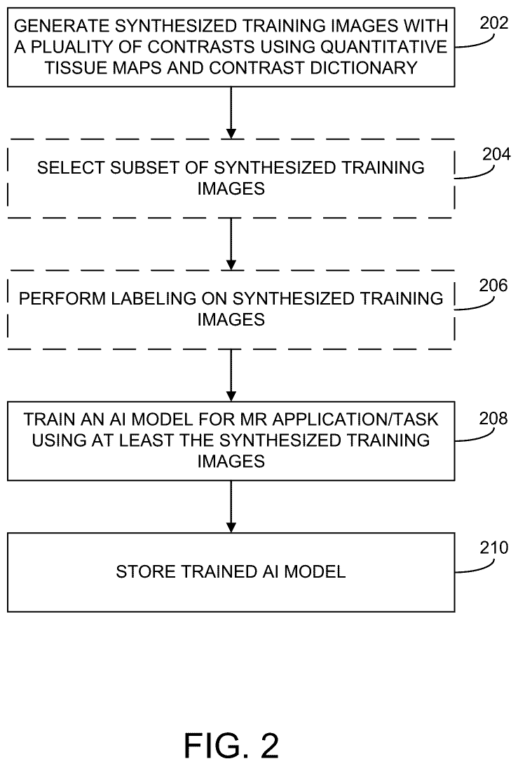

At block 106, a plurality of quantitative tissue maps for an anatomy of interest (e.g., brain, heart, lung, etc.) may be retrieved, for example, from memory or data storage of a computer system (e.g., computer system 700 shown in FIG. 7) or from memory or data storage of a MRI system (e.g., MRI system 600 shown in FIG. 6). In some embodiments, the plurality of quantitative tissue maps can include a modest number of quantitative tissue maps (e.g., less than 100). In some embodiments, the quantitative tissue maps can be acquired using an MRI system (e.g., MRI system 600 shown in FIG. 2) and one or more known techniques for acquiring MR data and generating a quantitative tissue map such as, for example magnetic resonance fingerprinting (MRF), T1 mapping, T2 mapping, quantitative susceptibility mapping (QSM), and magnetization transfer (MT) imaging. The quantitative tissue maps can include, for example, T1, T2, M0, B0, and B1. In some embodiments, each of the quantitative tissue map can be acquired using a different quantitative mapping technique, the same quantitative mapping technique, or a combination of quantitative mapping techniques. In some embodiments, each quantitative tissue map can be for the same subject or can be for a different subject. In some embodiments, the plurality of quantitative tissue maps can include two or more subsets of quantitative tissue maps where each subset can be for a different subject. For example, an MRF scan may generate multiple quantitative tissue maps for the same subject (e.g., T1, T2, proton density) and one of the subsets can include the three quantitative tissue maps for the particular subject.

At block 108, the contrast dictionary can be accessed, for example, from data storage. As used herein, the term “accessing” may refer to any number of activities related to retrieving or processing the contrast dictionary using, for example, MRI system 600 (shown in FIG. 6), computer system 700 (shown in FIG. 7), an extended network, information repository, or combination thereof. At block 110, one or more of the quantitative tissue maps can be selected from the plurality of quantitative tissue maps based on associated subject. In one example, if a first subject has one associated quantitative tissue map (e.g., T1), the one quantitative tissue map can be selected for processing at block 112. In another example, if a second subject has three associated quantitative tissue maps (e.g., T1, T2, proton density), the three tissue quantitative tissue maps can be selected for processing at block 112. In another example, if all of the quantitative tissue maps in the plurality of quantitative tissue maps are all associated with the same subject, all of the quantitative tissue maps can be selected for processing at block 112. At block 112, a plurality of MR images with a plurality of contrasts can be synthesized using the selected quantitative tissue map(s) and the contrast dictionary. In some embodiments, the number of synthesized MR images generated using the selected quantitative tissue map(s) can correspond to the number of synthesized signals (or columns) in a row of the contrast dictionary for each contrast value or combination of contrast values. Accordingly, a synthesized image corresponding to each combination of imaging factors or parameters can be synthesized from the quantitative tissue map(s). In an example for a single quantitative tissue map associated with first subject, a pixel or voxel from the quantitative tissue map can have an associated contrast value (e.g., either one type of contrast (e.g., T1, or a combination of two or more types of contrast (e.g., T1 and T2)). The row in the contrast dictionary corresponding to that contrast value provides a plurality of signals that generate that contrast with different combinations of imaging factor or parameters. According, a first image can include, for a pixel or voxel corresponding to the pixel or voxel from the quantitative tissue map, the signal in the contrast dictionary that corresponds to the contrast value of the pixel or voxel in the quantitative tissue map and a first combination of imaging factors or parameters that generated the contrast value. The first image can continue to be synthesized using signals from the contrast dictionary that correspond to the contrast value for each pixel or voxel in the quantitative tissue map and the same combination of imaging factors or parameters. In another example, if the selected quantitative tissue maps include two quantitative tissue maps for a second subject, each illustrating a different tissue property (e.g., T1 and T2), a pixel or voxel from the first quantitative tissue map can have an associated contrast value for T1) and the corresponding pixel in the second tissue map can have an associated contrast value for T2. The row in the contrast dictionary corresponding to that combination of contrast values (e.g., T1 and T2) provides a plurality of signals that generate those contrast values with different combinations of imaging factor or parameters. In this example, the synthesized MR images based on the two quantitative tissue maps can be completed as discussed above. As mentioned, the plurality of MR images with a plurality of contrasts can be simulated using one or more processor devices.

At block 114, image (or data) augmentation can be performed on the plurality of synthesized images to, for example, simulate randomization on the plurality of synthesized MR images. In some embodiments, noise, artifacts, or system inhomogeneity effects can be added to one or more of the synthesized images, or one or more image operations can be simulated on one or more of the synthesized MR images such as, for example, image cropping, rotating, down sampling, smoothing for data augmentation purposes. Performing image (or data) augmentation can, for example, further enhance the diversity of the synthesized MR images (e.g., for training an AI model as discussed below with respect to FIG. 2) and can improve the robustness of an AI model trained with the synthesized MR images to random errors that may occur during the acquisition of an MR image with an MRI system.

At block 116, if it is determined that there are additional quantitative tissue map(s) in the set of tissue maps, the process moves to block 110 and another one or more quantitative tissue maps can be selected from the plurality of quantitative tissue maps based on an associated subject and used with the contrast dictionary to synthesize a plurality of MR images with a plurality of contrasts at block 112. Accordingly, quantitative tissue map(s) in the plurality of quantitative tissue maps can be used to synthesize a plurality of MR images with a plurality of contrasts. If, at block 116, the last quantitative tissue map(s) in the set of quantitative tissue maps have been reached, the process can move to block 118. At block 118, the plurality of synthesized MR images with a plurality of contrasts can be stored in data storage or memory of, for example, an MRI system (e.g., MRI system 600 shown in FIG. 6) or a computer system (e.g., computer system 700 shown in FIG. 7).

In some embodiments, the described method for method for synthesizing MR images with a plurality of contrasts using a physics-based contrast dictionary and quantitative tissue maps can enable consistent quantification of tissue volumes across different scanner models, vendors, and MR sequences, and can facilitate quantitative and generalizable morphological measurement.

FIG. 2 illustrates a method for training a generalizable AI model for a magnetic resonance imaging application using synthesized MR training images with a plurality of contrasts in accordance with an embodiment. Although the blocks of the process of FIG. 2 are illustrated in a particular order, in some embodiments, one or more blocks may be executed in a different order than illustrated in FIG. 2, or may be bypassed. The process of FIG. 2 may be performed by a processing system including at least one electronic processor, where the at least one electronic processor may be or include a processor as described below (e.g., including one or more individual processor devices) with respect to FIGS. 6 and 7. For example, the process of FIG. 2 may be performed using a processor of MRI system 100 (e.g., processor 608) described below with respect to FIG. 6 or computer system 700 described below with respect to FIG. 7.

At block 202, MR images with a plurality of contrasts for training an AI model or network, referred to herein as training images, can be synthesized using a plurality of quantitative tissue maps and a contrast dictionary, for example, as described above with respect to FIG. 1. In some embodiments, the synthesized training images are images of the same anatomy (e.g., the brain, heart, lungs, etc.), for example, the anatomy related to the application or task the AI model or network is being trained to perform. As mentioned, the AI model can be trained to perform downstream analysis or tasks such as, for example, segmentation (e.g., tissue segmentation), harmonization (e.g., multi-site image harmonization), super-resolution, image registration and image enhancement, healthy brain atlas generation, healthy/aging brain characterization, and disease detection and characterization. In one example, the plurality of training images can be images of a brain for training an AI model for brain segmentation. The synthesized training images can be stored in data storage or memory of, for example, an MRI system (e.g., MRI system 600 shown in FIG. 6) or a computer system (e.g., computer system 700 shown in FIG. 7).

At block 204, a subset of the synthesized training images generated at block 202 can optionally be selected for training of the AI model. In some embodiments, a large number (e.g., tens of thousands, hundreds of thousands, millions) of training images may be synthesized at block 202 using the process described above with respect to FIG. 1. For training of an AI model, it may be advantageous to use a subset of the total number of synthesized images for training (e.g., to reduce total time for training, improve training efficiency). In one example, at block 202 a total of 10,000 synthesized training images may be generated, but for training of the AI model, only 1000 training images may be necessary. However, it is desirable to ensure that the selected subset of synthesized training images includes synthesized images that represent the different types of contrast. In some embodiments, known techniques can be used to select or sample synthesized training images that represent the different types of contrast that are included in the total number of synthesized images generated at block 202. For example, techniques such as singular value decomposition (SVD) can be used to select the subset of synthesized training images. In some embodiments, a low dimensional subspace can be randomly sampled to efficiently generate a subset of the synthesized training images that include a full range of image contrasts for comprehensive and efficient AI model or network training. As mentioned, the subset of training images can be selected (or sampled) using one or more processor devices. The selected subset of training images can be stored in data storage or memory of, for example, an MRI system (e.g., MRI system 600 shown in FIG. 6) or a computer system (e.g., computer system 700 shown in FIG. 7).

At block 206, the synthesized training images (or selected subset of the synthesized training images) may optionally be labeled if required by the technique used to train the AI model (e.g., supervised learning, semi-supervised learning, etc.). In some embodiments, all of the training images may be labeled, or some of the training images may be labeled and some of the training images unlabeled. In some embodiments, the synthesized training images can be labeled automatically (e.g., using one or more processor devices) using known techniques and/or the synthesized training images can be labeled manually. Labeling efficiency for automatic labeling methos can be improved because the synthesized training images include a variety of images for the same anatomy, e.g., an infinite number of contrast variations can be generated for the anatomy of interest. This can eliminate the need for contrast-specific re-labeling. In addition, reliability can be improved by enforcing labeling consistency across different contrasts. Accordingly, labels created for a specific contrast can be propagated across an infinite range of other contrasts. In some embodiments, synthesized training images with customized contrasts can enhance manual labeling (or annotation) by improving the visibility of structures with poor contrast such as, for example, the cerebellum for brain images. The labeled training images can be stored in data storage or memory of, for example, an MRI system (e.g., MRI system 600 shown in FIG. 6) or a computer system (e.g., computer system 700 shown in FIG. 7).

At block 208, the AI model can be trained to perform the desired application or task using at least the synthesized training images (or selected subset of the synthesized training images). The machine learning or AI model can be, for example, decision tree learning, association rule learning, an artificial neural network (e.g., a convolutional neural network (CNN), a generative adversarial network (GAN)), inductive logic programming, support vector machine, clustering, Bayesian network, reinforcement learning, representation learning, similarity and metric learning, sparse dictionary learning, and genetic algorithms. The AI model or network can be trained using known methods such as, for example, supervised learning, self-supervised learning, semi-supervised learning, etc. As one example, to perform supervised learning, the training data includes example inputs and corresponding desired (for example, actual) outputs, and the machine learning model progressively develops a model that maps inputs to the outputs included in the training data. As another example, to perform self-supervised learning, a model is trained on a task using the data itself to generate supervisory signals (e.g., unlabeled training data), rather than relying on, e.g., external labels provided by a user (e.g., labeled training data). As yet another example, to perform semi-supervised learning, the training data may include desired output values for a subset of the training data (e.g., labeled training data) while the remaining training data may be unlabeled or imprecisely labeled (e.g., unlabeled training data). As mentioned, the AI model can be trained using one or more processor devices. At block 210, the trained AI model or network can be stored in data storage or memory of, for example, an MRI system (e.g., MRI system 600 shown in FIG. 6) or a computer system (e.g., computer system 700 shown in FIG. 7).

As mentioned, conventionally trained AI models for MR applications or tasks (e.g., segmentation, etc.) can face challenges with generalizability as they are susceptible to, for example, site, age, and contrast variations. In some embodiments, an AI model or network trained using training images with a plurality of contrasts synthesized using a physics-based contrast dictionary and quantitative tissue maps can yield more accurate and reproducible results than conventional approaches, despite variances in characteristics of the MR image(s) being input to the trained AI model for analysis, for example, the subject anatomy of interest, scanner models, scanner vendors, MR sequences, and even the age of the subject (including extreme cases such as neonates). As mentioned, AI models trained using training images with a plurality of contrasts synthesized using a physics-based contrast dictionary and quantitative tissue maps can be used to process or analyze both clinical weighted MR images and quantitative MR images (e.g., quantitative T1 and T2 relaxation maps). In addition, the disclosed method for training a generalizable AI model for a magnetic resonance imaging application using a set of synthesized MR training images with a plurality of contrasts yields trained AI models that can be highly generalizable to use with images acquired with different acquisition parameters or conditions. Accordingly, AI models trained with synthesized training images as described above can be compatible with any type of MR scan. AI models trained with using the process described above can support a wide range of use cases, encompassing, for example, various diseases, anatomical structures, and even different species.

In some embodiments, AI models trained training images with a plurality of contrasts synthesized using a physics-based contrast dictionary and quantitative tissue maps can be seamlessly integrated into the clinical workflow to process, analyze, and compare clinical images (qualitative and quantitative). In one example, a segmentation AI model trained using the method and synthesized training images described above can automate quantification of morphological features, such as tissue volumes, in healthy, developing, and aging subjects. In another example, for input quantitative images of a subject, a segmentation AI model trained using the method and synthesized training images described above can automate quantification of tissue properties, such as relaxation times, myelin water fractions, and partial volume tissue fractions, in each segmented region. In some embodiments, an AI model can be trained using the process and synthesized training images described above can be used as an image harmonization tool for multi-site studies, providing consistent image analysis and reducing non-biological side-effects. In some embodiments, the training method and synthesized training images described above can be used to develop AI models for assessing neurodegenerative diseases and developmental delays, monitor disease progression, and detect lesions. In some embodiments, AI models trained using the method and synthesized training images described above can improve the robustness of disease diagnosis and prognosis tools for clinical decision support. In some embodiments, AI models trained using the method and synthesized training images described above can be used in virtual clinical trials for methodological evaluations.

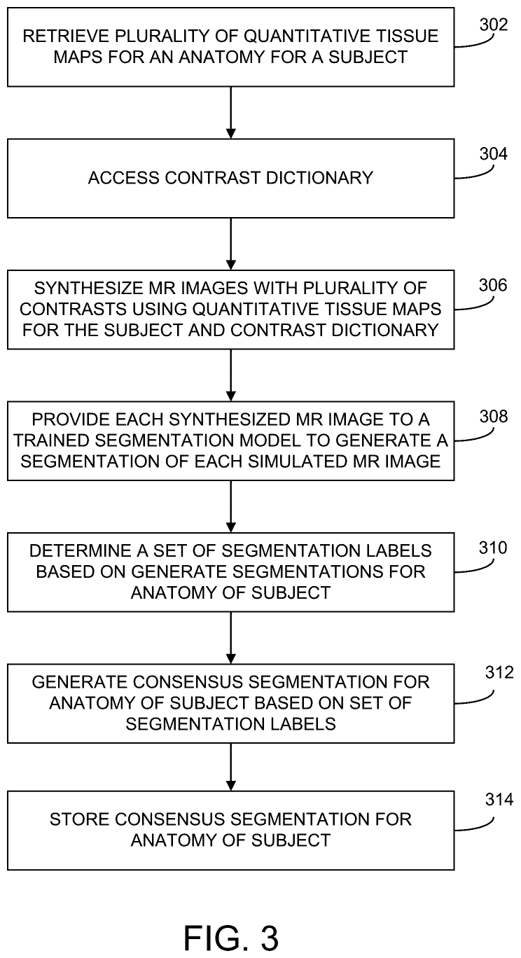

FIG. 3 illustrates a method for generating a consensus segmentation for an anatomy of a subject using synthesized MR images with a plurality of contrasts in accordance with an embodiment. Although the blocks of the process of FIG. 3 are illustrated in a particular order, in some embodiments, one or more blocks may be executed in a different order than illustrated in FIG. 3, or may be bypassed. The process of FIG. 3 may be performed by a processing system including at least one electronic processor, where the at least one electronic processor may be or include a processor as described below (e.g., including one or more individual processor devices) with respect to FIGS. 6 and 7. For example, the process of FIG. 3 may be performed using a processor of MRI system 100 (e.g., processor 608) described below with respect to FIG. 6 or computer system 700 described below with respect to FIG. 7.

At block 302, a plurality of quantitative tissue maps for an anatomy of interest (e.g., brain, heart, lung, etc.) for a single subject may be retrieved, for example, from memory or data storage of a computer system (e.g., computer system 700 shown in FIG. 7) or from memory or data storage of a MRI system (e.g., MRI system 600 shown in FIG. 6). In some embodiments, the set of quantitative tissue maps can include a modest number of quantitative tissue maps (e.g., less than 100). In some embodiments, the quantitative tissue maps can be acquired using an MRI system (e.g., MRI system 600 shown in FIG. 2) and one or more known techniques for acquiring MR data and generating a quantitative tissue map such as, for example magnetic resonance fingerprinting (MRF), T1 mapping, T2 mapping, quantitative susceptibility mapping (QSM), and magnetization transfer (MT) imaging. The quantitative tissue maps can include, for example, T1, T2, M0, B0, and B1. In some embodiments, each of the quantitative tissue map can be acquired using a different quantitative mapping technique, the same quantitative mapping technique, or a combination of quantitative mapping techniques. In an example, the set of quantitative tissue maps for the subject may include a T1 map of the anatomy of interest and a T2 map of the anatomy of interest. At block 304, a contrast dictionary can be accessed, for example, from data storage. In some embodiments, the contrast dictionary can be generated using a physics based signal model as described above with respect to block 102 of FIG. 1. As used herein, the term “accessing” may refer to any number of activities related to retrieving or processing the contrast dictionary using, for example, MRI system 600 (shown in FIG. 6), computer system 700 (shown in FIG. 7), an extended network, information repository, or combination thereof.

At block 306, MR images with a plurality of contrasts can be synthesized using the set of quantitative tissue maps and the contrast dictionary, for example, using the process as described above with respect to FIG. 1. In some embodiments, the synthesized MR images are images of the same anatomy as the set of quantitative tissue maps. The synthesized MR images can be stored in data storage or memory of, for example, an MRI system (e.g., MRI system 600 shown in FIG. 6) or a computer system (e.g., computer system 700 shown in FIG. 7). At block 308, each synthesized MR image from the plurality of synthesized MR images with a plurality of contrasts may be provided to a trained segmentation model or network trained to segment the anatomy included in the synthesized MR images. The trained segmentation model or network can be configured to generate a segmentation of the anatomy included in the synthesized MR image for each synthesized MR image provided to the trained segmentation model. In some embodiments, the trained segmentation model can be trained using the synthesized training images and process described above with respect to FIG. 2. In some embodiments, the trained segmentation model can be trained using other types of training images. The segmentation generated by the trained segmentation model for each synthesized MR image can be stored in data storage or memory of, for example, an MRI system (e.g., MRI system 600 shown in FIG. 6) or a computer system (e.g., computer system 700 shown in FIG. 7).

At block 310, a set of segmentation labels can be determined based on the generated segmentations for the anatomy of interest at block 308. At block 312, a consensus segmentation can be generated or estimated based on the set of segmentation labels. For example, in some embodiments, the segmentation labels can be averaged to find mutual information from the generated segmentation results. In another example, techniques such as voxel-wise majority voting can be applied to refine and consolidate the set of segmentation labels. At block 314, the estimated consensus segmentation for the anatomy of interest for the subject can be stored in data storage or memory of, for example, an MRI system (e.g., MRI system 600 shown in FIG. 6) or a computer system (e.g., computer system 700 shown in FIG. 7). Estimating a consensus segmentation for an anatomy of interest for a subject covering a range of image contrast synthesized for the same subject, facilitates the automatic generation of reliable image segmentation references. This can mitigate the reliance on manual delineation. In addition, estimating the consensus segmentation can result in higher accuracy and robustness than conventional segmentation approaches.

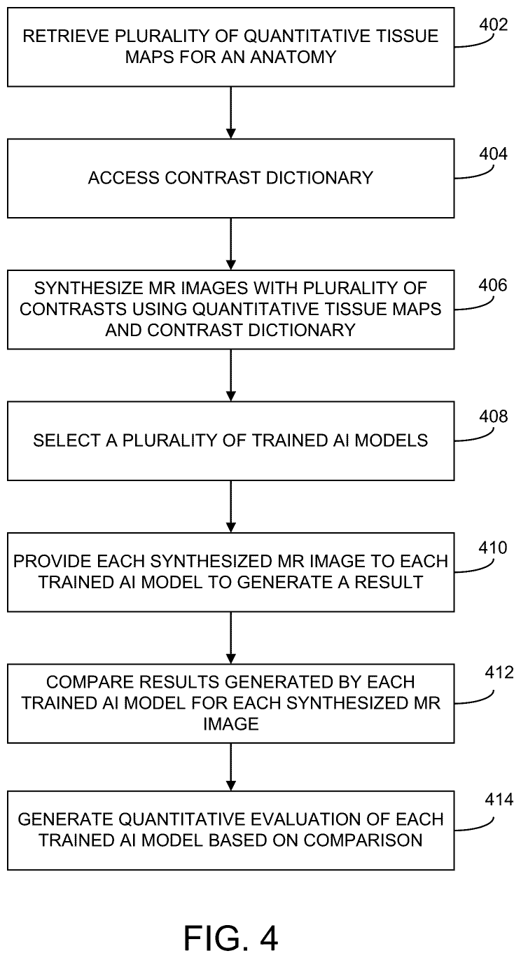

Before deployment, it is desirable to thoroughly evaluate trained AI models across various image contrasts. FIG. 4 illustrates a method for evaluating a plurality of trained AI models for an MR application using synthesized MR images with a plurality of contrasts in accordance with an embodiment. Although the blocks of the process of FIG. 4 are illustrated in a particular order, in some embodiments, one or more blocks may be executed in a different order than illustrated in FIG. 4, or may be bypassed. The process of FIG. 4 may be performed by a processing system including at least one electronic processor, where the at least one electronic processor may be or include a processor as described below (e.g., including one or more individual processor devices) with respect to FIGS. 6 and 7. For example, the process of FIG. 4 may be performed using a processor of MRI system 100 (e.g., processor 608) described below with respect to FIG. 6 or computer system 700 described below with respect to FIG. 7.

At block 402, a plurality of quantitative tissue maps for an anatomy of interest (e.g., brain, heart, lung, etc.) may be retrieved, for example, from memory or data storage of a computer system (e.g., computer system 700 shown in FIG. 7) or from memory or data storage of a MRI system (e.g., MRI system 600 shown in FIG. 6). In some embodiments, the set of quantitative tissue maps can include a modest number of quantitative tissue maps (e.g., less than 100). In some embodiments, the quantitative tissue maps can be acquired using an MRI system (e.g., MRI system 600 shown in FIG. 2) and one or more known techniques for acquiring MR data and generating a quantitative tissue map such as, for example magnetic resonance fingerprinting (MRF), T1 mapping, T2 mapping, quantitative susceptibility mapping (QSM), and magnetization transfer (MT) imaging. The quantitative tissue maps can include, for example, T1, T2, M0, B0, and B1. In some embodiments, each of the quantitative tissue map can be acquired using a different quantitative mapping technique, the same quantitative mapping technique, or a combination of quantitative mapping techniques. In some embodiments, each quantitative tissue map can be for the same subject or can be for a different subject. In some embodiments, the plurality of quantitative tissue maps can include two or more subsets of quantitative tissue maps where each subset can be for a different subject. At block 404, a contrast dictionary can be accessed, for example, from data storage. In some embodiments, the contrast dictionary can be generated using a physics based signal model as described above with respect to block 102 of FIG. 1. As used herein, the term “accessing” may refer to any number of activities related to retrieving or processing the contrast dictionary using, for example, MRI system 600 (shown in FIG. 6), computer system 700 (shown in FIG. 7), an extended network, information repository, or combination thereof.

At block 406, MR images with a plurality of contrasts can be synthesized using the plurality of quantitative tissue maps for the anatomy of interest and the contrast dictionary, for example, using the process as described above with respect to FIG. 1. In some embodiments, the synthesized MR images are images of the same anatomy as the set of quantitative tissue maps. The synthesized MR images can be stored in data storage or memory of, for example, an MRI system (e.g., MRI system 600 shown in FIG. 6) or a computer system (e.g., computer system 700 shown in FIG. 7).

At block 408, a plurality of trained AI models can be selected and each selected trained AI model is trained for the same application or task (e.g., segmentation, classification, registration, etc.). In some embodiments, one or more of the trained AI models can be trained using the synthesized training images and process described above with respect to FIG. 2. In some embodiments, one or more of the trained AI models can be trained using other types of training images. At block 410, each synthesized MR image generated at block 406 can be provided to each trained AI model or network to generate a result. For example, if five trained segmentation models are selected, each synthesized MR image can be provided to each segmentation model to generate a segmentation for each synthesized MR image. Accordingly, in this example, five segmentations for each synthesized MR image can be acquired, namely, one segmentation is generated for a synthesized MR image by each segmentation model. At block 412, the results generated by each trained AI model for a synthesized MR image can then be compared. At block 414, a quantitative evaluation of each trained AI model can be generated based on the comparison.

In some embodiments, the described method for evaluating a plurality of trained AI models for an MR application using a set of synthesized MR images with a plurality of contrasts can allow for the systematic and comprehensive evaluation of the contrast dependency of computational AI models or networks developed for MRI. The process described with respect to FIG. 4 can simulate diverse and realistic MR images for an anatomy of interest and offer a platform for stress-testing trained AI models and, for example, quantifying uncertainty, ensuring AI model effectiveness across diverse datasets, vendors, and age groups.

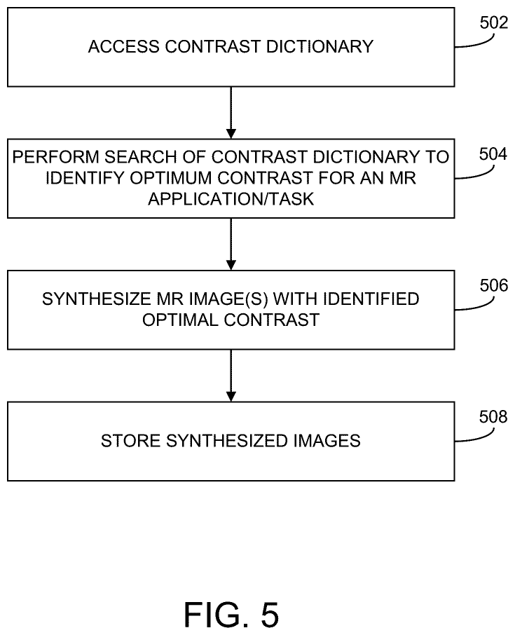

FIG. 5 illustrates a method for determining an optimal contrast for an MR application using a contrast dictionary in accordance with an embodiment. Although the blocks of the process of FIG. 5 are illustrated in a particular order, in some embodiments, one or more blocks may be executed in a different order than illustrated in FIG. 5, or may be bypassed. The process of FIG. 5 may be performed by a processing system including at least one electronic processor, where the at least one electronic processor may be or include a processor as described below (e.g., including one or more individual processor devices) with respect to FIGS. 6 and 7. For example, the process of FIG. 5 may be performed using a processor of MRI system 100 (e.g., processor 608) described below with respect to FIG. 6 or computer system 700 described below with respect to FIG. 7.

At block 502, a contrast dictionary can be accessed, for example, from data storage. In some embodiments, the contrast dictionary can be generated using a physics based signal model as described above with respect to block 102 of FIG. 1. As used herein, the term “accessing” may refer to any number of activities related to retrieving or processing the contrast dictionary using, for example, MRI system 600 (shown in FIG. 6), computer system 700 (shown in FIG. 7), an extended network, information repository, or combination thereof.

At block 504, a search can be performed of the contrast dictionary to identify an optimal contrast or contrasts for a selected MR application or task (e.g., segmentation, registration, etc.). For example, for separating out two tissue types, may want to find the contrast with the largest intensity or magnitude difference between the two tissue types. The search of the contrast dictionary can be performed using known techniques. Once the optimal contrast or contrasts have been identified one or more MR images can be synthesized at block 506 with the identified optimal contrast using the signals corresponding to the optimal contrast(s) in the contrast dictionary. At block 508, the synthesized images with the identified optimal contrast can be stored in data storage or memory of, for example, an MRI system (e.g., MRI system 600 shown in FIG. 6) or a computer system (e.g., computer system 700 shown in FIG. 7). In some embodiments, the MR images synthesized using the optimal or optimized contrast can be used for manual labeling, for example, for training images for an AI model.

FIG. 6 shows an example of an MRI system 600 that may be used to implement the methods described herein. MRI system 600 includes an operator workstation 602, which may include a display 604, one or more input devices 606 (e.g., a keyboard, a mouse), and a processor 608. The processor 608 may include a commercially available programmable machine running a commercially available operating system. The operator workstation 602 provides an operator interface that facilitates entering scan parameters into the MRI system 600. The operator workstation 602 may be coupled to different servers, including, for example, a pulse sequence server 610, a data acquisition server 612, a data processing server 614, and a data store server 616. The operator workstation 602 and the servers 610, 612, 614, and 616 may be connected via a communication system 640, which may include wired or wireless network connections.

The pulse sequence server 610 functions in response to instructions provided by the operator workstation 602 to operate a gradient system 618 and a radiofrequency (“RF”) system 620. Gradient waveforms for performing a prescribed scan are produced and applied to the gradient system 618, which then excites gradient coils in an assembly 622 to produce the magnetic field gradients Gₓ, G_{y}, and G_{z} that are used for spatially encoding magnetic resonance signals. The gradient coil assembly 622 forms part of a magnet assembly 624 that includes a polarizing magnet 626 and a whole-body RF coil 628.

RF waveforms are applied by the RF system 620 to the RF coil 628, or a separate local coil to perform the prescribed magnetic resonance pulse sequence. Responsive magnetic resonance signals detected by the RF coil 628, or a separate local coil, are received by the RF system 620. The responsive magnetic resonance signals may be amplified, demodulated, filtered, and digitized under direction of commands produced by the pulse sequence server 610. The RF system 620 includes an RF transmitter for producing a wide variety of RF pulses used in MRI pulse sequences. The RF transmitter is responsive to the prescribed scan and direction from the pulse sequence server 610 to produce RF pulses of the desired frequency, phase, and pulse amplitude waveform. The generated RF pulses may be applied to the whole-body RF coil 628 or to one or more local coils or coil arrays.

The pulse sequence server 610 may receive patient data from a physiological acquisition controller 630. By way of example, the physiological acquisition controller 630 may receive signals from a number of different sensors connected to the patient, including electrocardiogramaignals from electrodes, or respiratory signals from a respiratory bellows or other respiratory monitoring devices. These signals may be used by the pulse sequence server 610 to synchronize, or “gate,” the performance of the scan with the subject's heartbeat or respiration.

The pulse sequence server 610 may also connect to a scan room interface circuit 632 that receives signals from various sensors associated with the condition of the patient and the magnet system. Through the scan room interface circuit 632, a patient positioning system 634 can receive commands to move the patient to desired positions during the scan.

The digitized magnetic resonance signal samples produced by the RF system 620 are received by the data acquisition server 612. The data acquisition server 612 operates in response to instructions downloaded from the operator workstation 602 to receive the real-time magnetic resonance data and provide buffer storage, so that data is not lost by data overrun. In some scans, the data acquisition server 612 passes the acquired magnetic resonance data to the data processor server 614. In scans that require information derived from acquired magnetic resonance data to control the further performance of the scan, the data acquisition server 612 may be programmed to produce such information and convey it to the pulse sequence server 610. For example, during pre-scans, magnetic resonance data may be acquired and used to calibrate the pulse sequence performed by the pulse sequence server 610. As another example, navigator signals may be acquired and used to adjust the operating parameters of the RF system 620 or the gradient system 618, or to control the view order in which k-space is sampled. In still another example, the data acquisition server 612 may also process magnetic resonance signals used to detect the arrival of a contrast agent in a magnetic resonance angiography (“MRA”) scan. For example, the data acquisition server 612 may acquire magnetic resonance data and processes it in real-time to produce information that is used to control the scan.

The data processing server 614 receives magnetic resonance data from the data acquisition server 612 and processes the magnetic resonance data in accordance with instructions provided by the operator workstation 602. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 614 are conveyed back to the operator workstation 602 for storage. Real-time images may be stored in a data base memory cache, from which they may be output to operator display 602 or a display 636. Batch mode images or selected real time images may be stored in a host database on disc storage 638. When such images have been reconstructed and transferred to storage, the data processing server 614 may notify the data store server 616 on the operator workstation 602. The operator workstation 602 may be used by an operator to archive the images, produce films, or send the images via a network to other facilities.

The MRI system 600 may also include one or more networked workstations 642. For example, a networked workstation 642 may include a display 644, one or more input devices 646 (e.g., a keyboard, a mouse), and a processor 648. The networked workstation 642 may be located within the same facility as the operator workstation 602, or in a different facility, such as a different healthcare institution or clinic.

The networked workstation 642 may gain remote access to the data processing server 614 or data store server 616 via the communication system 640. Accordingly, multiple networked workstations 642 may have access to the data processing server 614 and the data store server 616. In this manner, magnetic resonance data, reconstructed images, or other data may be exchanged between the data processing server 614 or the data store server 616 and the networked workstations 642, such that the data or images may be remotely processed by a networked workstation 642.

FIG. 7 is a block diagram of an example computer system in accordance with an embodiment. Computer system 700 may be used to implement the systems and methods described herein. In some embodiments, the computer system 700 may be a workstation, a notebook computer, a tablet device, a mobile device, a multimedia device, a network server, a mainframe, one or more controllers, one or more microcontrollers, or any other general-purpose or application-specific computing device. The computer system 700 may operate autonomously or semi-autonomously, or may read executable software instructions from the memory or storage device 716 or a computer-readable medium (e.g., a hard drive, a CD-ROM, flash memory), or may receive instructions via the input device 720 from a user, or any other source logically connected to a computer or device, such as another networked computer or server. Thus, in some embodiments, the computer system 700 can also include any suitable device for reading computer-readable storage media.

Data, such as data acquired with, for example, an imaging system (e.g., a magnetic resonance imaging (MRI) system, etc.), may be provided to the computer system 700 from a data storage device 716, and these data are received in a processing unit 702. In some embodiments, the processing unit 702 included one or more processors. For example, the processing unit 702 may include one or more of a digital signal processor (DSP) 704, a microprocessor unit (MPU) 706, and a graphic processing unit (GPU) 708. The processing unit 702 also includes a data acquisition unit 710 that is configured to electronically receive data to be processed. The DSP 704, MPU 706, GPU 708, and data acquisition unit 710 are all coupled to a communication bus 712. The communication bus 712 may be, for example, a group of wires, or a hardware used for switching data between the peripherals or between any component in the processing unit 702.

The processing unit 702 may also include a communication port 714 in electronic communication with other devices, which may include a storage device 716, a display 718, and one or more input devices 720. Examples of an input device 720 include, but are not limited to, a keyboard, a mouse, and a touch screen through which a user can provide an input. The storage device 716 may be configured to store data, which may include data such as, for example, MRI data, images, quantitative maps, synthesized images, quantitative parameters, segmented images, etc., whether these data are provided to, or processed by, the processing unit 702. The display 718 may be used to display images, reports, and other information, such as patient health data, and so on.

The processing unit 702 can also be in electronic communication with a network 722 to transmit and receive data and other information. The communication port 714 can also be coupled to the processing unit 702 through a switched central resource, for example the communication bus 712. The processing unit 702 can also include temporary storage 724 and a display controller 726. The temporary storage 724 is configured to store temporary information. For example, the temporary storage 724 can be a random-access memory.

Computer-executable instructions for RF based frequency encoding with Bloch-Siegert shift and simultaneous transmit and receive according to the above-described methods may be stored on a form of computer readable media. Computer readable media includes volatile and nonvolatile, removable, and non-removable media implemented in any method or technology for storage of information such as computer readable instructions, data structures, program modules or other data. Computer readable media includes, but is not limited to, random access memory (RAM), read-only memory (ROM), electrically erasable programmable ROM (EEPROM), flash memory or other memory technology, compact disk ROM (CD-ROM), digital volatile disks (DVD) or other optical storage, magnetic cassettes, magnetic tape, magnetic disk storage or other magnetic storage devices, or any other medium which can be used to store the desired instructions and which may be accessed by a system (e.g., a computer), including by internet or other computer network form of access.

The present invention has been described in terms of one or more preferred embodiments, and it should be appreciated that many equivalents, alternatives, variations, and modifications, aside from those expressly stated, are possible and within the scope of the invention.

1. A method for synthesizing magnetic resonance (MR) images with a plurality of contrasts, the method comprising:
generating, using a processor device, a contrast dictionary using a physics-based signal model;
retrieving, using the processor device, a plurality of quantitative tissue maps for an anatomy of interest for one or more subjects;
synthesizing, using the processor device, a plurality of MR images with a plurality of contrasts using the plurality of quantitative tissue maps and the contrast dictionary; and
storing, using the processor device, the plurality of synthesized MR images in a data storage.

2. The method according to claim 1, further comprising performing image augmentation on one or more of the plurality of synthesized MR images.

3. The method according to claim 1, wherein the physics-based signal model is one or more of the Bloch equations or the Bloch-Torrey equations.

4. The method according to claim 1, wherein the contrast dictionary includes simulated signals having a plurality of different contrast values generated using different combinations of tissue properties and scan parameters.

5. The method according to claim 1, wherein each of the plurality of synthesized MR images includes simulated signals from the contrast dictionary corresponding to the same scan parameters.

6. The method according to claim 1, further comprising:
training, using the processor device, an artificial intelligence (AI) model for a predetermined task using the plurality of synthesized MR images as training images; and
storing, using the processor device, the trained AI model in data storage.

7. The method according to claim 6, further comprising:
selecting, using the processor device, a subset of the plurality of synthesized MR images as the training images; and
performing, using the processor device, labeling on one or more of the synthesized MR images in the subset of the plurality of synthesized MR images.

8. The method according to claim 6, wherein the predetermined task includes one or segmentation, harmonization, image registration, image enhancement, atlas generation, characterization, or disease detection.

9. The method according to claim 1, wherein the plurality of quantitative tissue maps for the anatomy of interest are for a single subject, the method further comprising:
providing, using the processor device, each synthesized MR image to a trained segmentation AI model to generate a segmentation for each synthesized MR image;
determining, using the processor device, a set of segmentation labels based on the segmentation generated by the segmentation AI model for each synthesized MR image; and
generating, using the processor device, a consensus segmentation for the anatomy of interest of the subject based on the set of segmentations labels.

10. The method according to claim 1, further comprising:
selecting, using the processor device, a plurality of trained AI models for a predetermined task, wherein each trained AI model generates a result based on the predetermined task;
providing, using the processor device, each synthesized MR image to each trained AI model to generate the result for each synthesized MR image; and
comparing, using the processor device, for each synthesized MR image, the result generated by each trained AI model.

11. A system for synthesizing magnetic resonance (MR) images with a plurality of contrasts, the system comprising:
a memory that stores one or more computer readable media that includes instructions; and
one or more processor devices configured to execute the instructions of the computer readable media to:
generate a contrast dictionary using a physics-based signal model;
retrieve a plurality of quantitative tissue maps for an anatomy of interest for one or more subjects;
synthesize a plurality of MR images with a plurality of contrasts using the plurality of quantitative tissue maps and the contrast dictionary; and
store the plurality of synthesized MR images in a data storage.

12. The system according to claim 11, wherein the one or more processor devices configured to execute the instructions of the computer readable media to perform image augmentation on one or more of the plurality of synthesized MR images.

13. The system according to claim 11, wherein the physics-based signal model is one or more of the Bloch equations or the Bloch-Torrey equations.

14. The system according to claim 11, wherein the contrast dictionary includes simulated signals having a plurality of different contrast values generated using different combinations of tissue properties and scan parameters.

15. The system according to claim 11, wherein each of the plurality of synthesized MR images includes simulated signals from the contrast dictionary corresponding to the same scan parameters.

16. The system according to claim 11, wherein the one or more processor devices configured to execute the instructions of the computer readable media to:
train an artificial intelligence (AI) model for a predetermined task using the plurality of synthesized MR images as training images; and
store the trained AI model in data storage.

17. The system according to claim 16, wherein the one or more processor devices configured to execute the instructions of the computer readable media to:
select a subset of the plurality of synthesized MR images as the training images; and
perform labeling on one or more of the synthesized MR images in the subset of the plurality of synthesized MR images.

18. The system according to claim 16, wherein the predetermined task includes one or segmentation, harmonization, image registration, image enhancement, atlas generation, characterization, or disease detection.

19. The system according to claim 11, wherein the plurality of quantitative tissue maps for the anatomy of interest are for a single subject, and wherein the one or more processor devices configured to execute the instructions of the computer readable media to:
provide each synthesized MR image to a trained segmentation AI model to generate a segmentation for each synthesized MR image;
determine a set of segmentation labels based on the segmentation generated by the segmentation AI model for each synthesized MR image; and
generate a consensus segmentation for the anatomy of interest of the subject based on the set of segmentations labels.

20. The system according to claim 11, wherein the one or more processor devices configured to execute the instructions of the computer readable media to:
select a plurality of trained AI models for a predetermined task, wherein each trained AI model generates a result based on the predetermined task;
provide each synthesized MR image to each trained AI model to generate the result for each synthesized MR image; and
compare for each synthesized MR image, the result generated by each trained AI model.
